(19) United States
(12) Patent Application Publication
(10) Pub. No.: US 2021/0142963 A1
(43) Pub. Date: May 13, 2021

(54) TRIGGER DEVICE

(71) Applicant: SUNREX TECHNOLOGY CORP., Taichung City (TW)

(72) Inventors: Chun-Chieh CHEN, Taichung City (TW); Ling-Cheng TSENG, Taichung City (TW); Ching-Yao HUANG, Taichung City (TW)

(73) Assignee: SUNREX TECHNOLOGY CORP., Taichung City (TW)

(21) Appl. No.: 16/834,190

(22) Filed: Mar. 30, 2020

(30) Foreign Application Priority Data
Nov. 12, 2019 (TW) 108214985

(51) Int. Cl. H01H 13/10; H05K 1/18; H01H 13/52; H01H 13/12

(52) U.S. Cl. CPC H01H 13/10; H05K 1/18; H01H 13/52; H01H 2227/002; H05K 2201/10053; H01H 2221/062; H01H 13/12

(57) ABSTRACT

A trigger device includes a circuit board, an arched sheet, and a noise-reducing unit that includes first and second electroconductive sheets respectively connected to first and second nodes of the circuit board. The arched sheet is mounted to the second electroconductive sheet and is pressible from a preset state to a bent state, with the arched sheet being deformed and proximate to the first electroconductive sheet, and further from the bent state to a contact state, with the second electroconductive sheet being compressed and with a central portion of the arched sheet being brought into contact with the first electroconductive sheet to thus electrically connect the first and second nodes.

### CROSS-REFERENCE TO RELATED APPLICATION

This application claims priority of Taiwanese Utility Model Patent Application No. 108214985, filed on Nov. 12, 2019.

### FIELD

The disclosure relates to a trigger device, more particularly to a trigger device with noise-reducing capabilities.

### BACKGROUND

A conventional push switch includes a substrate with an electronic circuit disposed thereon, and a metal dome disposed on the substrate. A user may press to deform the metal dome such that the metal dome contacts the substrate, which makes the electronic circuit of the substrate generate a pressing signal to achieve detection of the pressing action of the user. However, vibration resulting from deformation of the metal dome and contact between the metal dome and the substrate generate noise which negatively impacts user experience.

### SUMMARY

Therefore, the object of the disclosure is to provide a trigger device that can alleviate the drawback of the prior art.

According to the disclosure, a trigger device includes a circuit board, an arched sheet and a noise-reducing unit.

The circuit board includes an electronic circuit having a first node and a second node. A pressing signal is generated when the first and second nodes are electrically connected.

The arched sheet has a central portion, a surrounding portion surrounding the central portion, and a flexible portion interconnecting the central portion and the surrounding potion. The central portion protrudes along a pressing axis away from the circuit board.

The noise-reducing unit is connected between the circuit board and the arched sheet, and includes first and second electroconductive sheets mounted to the circuit board and respectively and electrically connected to the first and second nodes. The first electroconductive sheet is aligned with the central portion of the arched sheet along the pressing axis and has a first thickness along the pressing axis. The second electroconductive sheet is spaced apart from and surrounds the first electroconductive sheet, is compressible along the pressing axis, and has a second thickness along the pressing axis which is larger than the first thickness. The surrounding portion of the arched sheet is mounted to the second electroconductive sheet.

The arched sheet is pressible, relative to the noise-reducing unit, from a preset state to a bent state with the flexible portion being deformed and with the central portion being moved along the pressing axis toward the first electroconductive sheet to a position being proximate to the first electroconductive sheet.

The arched sheet is further pressible relative to the noise-reducing unit from the bent state to a contact state with the second electroconductive sheet being compressed along the pressing axis and with the central portion being brought into contact with the first electroconductive sheet to form an electrical connection therebetween and to thus electrically connect the first and second nodes.

### BRIEF DESCRIPTION OF THE DRAWINGS

Other features and advantages of the disclosure will become apparent in the following detailed description of the embodiment with reference to the accompanying drawings, of which:

FIG. 1 is a top view of an embodiment of a trigger device according to the disclosure;

FIG. 2 is a fragmentary and schematic enlarged view of FIG. 1;

FIG. 3 is is a fragmentary sectional view taken along line III-III in FIG. 2, illustrating an arched sheet of the embodiment in a preset state and illustrating the arched sheet in a bent state in dashed lines; and

FIG. 4 is similar to FIG. 3 but illustrating the arched sheet in a contact state.

### DETAILED DESCRIPTION

Referring to FIGS. 1 to 3, an embodiment of a trigger device according to the disclosure includes a circuit board 1, an arched sheet 2, and a noise-reducing unit 3.

The circuit board 1 includes an electronic circuit 100 for detecting a pressing action. The electronic circuit 100 has a first node 101 and a second node 102 that are spaced apart from each other. A pressing signal is generated when the first and second nodes 101, 102 are electrically connected. It should be noted that the electronic circuit 100 shown in FIG. 3 is a schematic circuit diagram to aid understanding of the disclosure and does not represent actual physical structure.

The arched sheet 2 has a central portion 21, a surrounding portion 22 surrounding the central portion 21, and a flexible portion 23 interconnecting the central portion 21 and the surrounding potion 22. The central portion 21 protrudes along a pressing axis (X) away from the circuit board 1.

The noise-reducing unit 3 is connected between the circuit board 1 and the arched sheet 2, and includes first and second electroconductive sheets 31, 32 mounted to the circuit board 1 and respectively and electrically connected to the first and second nodes 101, 102. The first electroconductive sheet 31 is aligned with the central portion 21 of the arched sheet 2 along the pressing axis (X) and has a first thickness (D1) along the pressing axis (X). The second electroconductive sheet 32 is spaced apart from and surrounds the first electroconductive sheet 31, is compressible along the pressing axis (X), and has a second thickness (D2) along the pressing axis (X) which is larger than the first thickness (Dl). The surrounding portion 22 of the arched sheet 2 is mounted to the second electroconductive sheet 32.

In this embodiment, the first electroconductive sheet 31 is substantially circular and is a copper foil, and the second electroconductive sheet 32 is annular, surrounds the first electroconductive sheet 31, and is made of electrically conductive non-woven fabric. However, the shapes and materials of the first and second electroconductive sheets 31, 32 is not thus limited and may have other configurations. For example, in other embodiments, the first electroconductive sheet 31 maybe an aluminum foil and have a non-circular shape.

Referring to FIGS. 2, 3, and 4, the arched sheet 2 is pressible, relative to the noise-reducing unit 3, from a preset state to a bent state (schematically shown by the dashed lines in FIG. 3) and further to a contact state (see FIG. 4). When the arched sheet 2 is not pressed (i.e., in the preset state), the central portion 21 is distal and spaced apart from the first electroconductive sheet 31. When the arched sheet 2 is pressed, the arched sheet 2 is first converted from the preset state to the bent state, in which the flexible portion 23 is deformed such that the central portion 21 moves along the pressing axis (X) to be closer to the first electroconductive sheet 31 and is proximate to but not in contact with the first electroconductive sheet 31. When the arched sheet 2 is further pressed, the arched sheet 2 is then converted from the bent state to the contact state, in which the second electroconductive sheet 32 is deformed and compressed along the pressing axis (X) and the central portion 21 is brought into contact with the first electroconductive sheet 31 to form the electrical connection between the central portion 21 and the first electroconductive sheet 31 to thus electrically connect the first and second nodes 101, 102 to generate the pressing signal.

Unless the arched sheet 2 is pressed, it remains in the preset state where the central portion 21 is spaced apart from the first electroconductive sheet 31 and the first and second nodes 101, 102 are not electrically connected, hence, the pressing signal is not produced. It should be noted that in the bent state, since the central portion 21 is not yet in contact with the first electroconductive sheet 31, the pressing signal is not produced either. However, deformation of the arched sheet 2 is nearly completed during the conversion of the arched sheet 2 from the preset state to the bent state, and the conversion of the arched sheet 2 from the bent state to the contact state mainly relies on the compression of the second electroconductive sheet 32. In the contact state, as the first and second nodes 101, 102 are electrically connected via the arched sheet 2, the pressing signal is generated. When the pressing force is released from the arched sheet 2, the second electroconductive sheet 32 decompressed and the arched sheet 2 is restored resiliently to the preset state.

In certain embodiments, a difference between the second thickness (D2) of the second electroconductive sheet 32 and the first thickness (Dl) of the first electroconductive sheet 31 is larger than 0.08 millimeters, which may contribute to desirable noise-reducing effects. In this embodiment, the difference between the second thickness (D2) and the first thickness (D1) is substantially equal to 0.1 millimeters.

Compared with the conventional push switch, where the pressing action involves only a single stage deformation of a metal dome being bent to contact a substrate, the trigger device of the disclosure allows the pressing action to be split into a bent process, where the arched sheet 2 changes from the preset state to the bent state, and a compressing process, where the arched sheet 2 changes from the bent state to the contact state. During the bent process, most of the deformation of the arched sheet 2 is complete, and the second electroconductive sheet 32 is not yet compressed and can absorb any vibration resulting from the deformation of the arched sheet 2 to reduce noise. In the compression process, the second electroconductive sheet 32 also acts as cushioning to absorb vibrations as the central portion 21 of the arched sheet 2 contacts the first electroconductive sheet 31 and hence also reduces noise. In other words, noise is reduced in both processes.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A trigger device comprising:
a circuit board including an electronic circuit that has a first node and a second node, a pressing signal being generated when said first and second nodes are electrically connected;
an arched sheet having a central portion, a surrounding portion that surrounds said central portion, and a flexible portion that interconnects said central portion and said surrounding potion, said central portion protruding along a pressing axis away from said circuit board; and
a noise-reducing unit connected between said circuit board and said arched sheet, and including first and second electroconductive sheets that are mounted to said circuit board and that are respectively and electrically connected to said first and second nodes, said first electroconductive sheet being aligned with said central portion of said arched sheet along the pressing axis and having a first thickness along the pressing axis, said second electroconductive sheet being spaced apart from and surrounding said first electroconductive sheet, being compressible along the pressing axis, and having a second thickness along the pressing axis which is larger than said first thickness, said surrounding portion of said arched sheet being mounted to said second electroconductive sheet;
wherein said arched sheet is pressible, relative to said noise-reducing unit, from a preset state to a bent state with said flexible portion being deformed and with said central portion being moved along the pressing axis toward said first electroconductive sheet to a position being proximate to said first electroconductive sheet; and
wherein said arched sheet is further pressible relative to said noise-reducing unit from the bent state to a contact state with said second electroconductive sheet being compressed along the pressing axis and with said central portion being brought into contact with said first electroconductive sheet to form an electrical connection therebetween and to thus electrically connect said first and second nodes.

2. The trigger device as claimed in claim 1, wherein said first electroconductive sheet is a copper foil.

3. The trigger device as claimed in claim 1, wherein said first electroconductive sheet is an aluminum foil.

4. The trigger device as claimed in claim 1, wherein said first electroconductive sheet is substantially circular.

5. The trigger device as claimed in claim 1, wherein said second electroconductive sheet is made of electrically conductive non-woven fabric.

6. The trigger device as claimed in claim 1, wherein said second electroconductive sheet is annular and surrounds said first electroconductive sheet.

7. The trigger device as claimed in claim 1, wherein a difference between said second thickness and said first thickness is larger than 0.08 millimeters.

8. The trigger device as claimed in claim 7, wherein said difference between said second thickness and said first thickness is substantially equal to 0.1 millimeters.
